(19) United States
(12) Patent Application Publication
(10) Pub. No.: US 2005/0136648 A1
(43) Pub. Date: Jun. 23, 2005

(54) Method and system for forming a contact in a thin-film device

(76) Inventors: Mariah Sharma, Mountain View, CA (US); Thomas C. Anthony, Sunnyvale, CA (US); Heon Lee, Pohang-Si (KR)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/745,723

(22) Filed: Dec. 23, 2003

(51) Int. Cl. H01L 21/4763; H01L 21/44

(52) U.S. Cl. 438/637; 438/670; 438/951

(57) ABSTRACT

An aspect of the present invention is a method of forming a contact in a thin-film device. The method includes forming a liftoff stencil, depositing at least one material through the liftoff stencil, removing a portion of the liftoff stencil, depositing a dielectric material, planarizing the dielectric material thereby exposing a portion of the at least one material and depositing a conductor material in contact with the exposed portion of the at least one material.

### FIELD OF THE INVENTION

The present invention relates generally to semiconductor devices and more particularly to a method and system for forming a contact in a thin-film device.

### BACKGROUND OF THE INVENTION

Along with rapid growth of information communicating apparatuses, particularly in the field of personal-use down-sized communication apparatuses such as a PDA (Personal Digital Assistant), higher integration, faster speed, and lower power consumption are demanded against memory elements and logic elements available for constituting these communicating apparatuses. In particular, realization of higher density and greater capacity of non-volatile memories has become a more important issue for the art of replacing such a hard disk or an optical disk which is intrinsically unable to be down-sized due to presence of moving elements.

Current non-volatile memories include flash memory, which is based on a semiconductor technology and FRAM (Ferro-electric Random Access Memory), which is based on a ferro-dielectric technology, for example. Nevertheless, flash memory is still problematic in that the writing speed remains on the order of micro-seconds. On the other hand, FRAM is problematic in that it is difficult to scale to ultra-high density and the re-writable cycles are insufficient.

A magnetic random access memory (MRAM) is free from the above-described problems. Due to improvement in physical characteristics of a TMR (Tunnel Magneto-Resistive) material in recent years, MRAM memory has drawn attention in this field.

Because of its simple constitution, MRAM can readily be formed into highly integrated configurations. Inasmuch as MRAM executes a write operation by rotation of a magnetic moment, it is possible to secure sufficient re-writable cycles. Further, it is expected that the MRAM memory can execute accessing operation at an extremely high-speed (for example, on the order of nano-seconds). Conventional MRAM manufacturing methods don't typically utilize a lift-off technique. However, this technique is used in the manufacture of abutted-junction magnetoresistive recording heads for hard disk drives. Using photo-resist for a mask material in forming elements, this method uses a single masking step to pattern one material by an etching process and a second material by a subsequent deposition and lift-off process. The resulting structure has a region of contact between the etched and lifted films defined by the boundary of the photo-resist mask.

This implementation creates a contact region between two films in the same plane. However, for many device applications it is desirable to produce a contact region between films on different planes. In particular, it is desirable that the contact does not introduce an electrical short circuit across the device being contacted.

Accordingly, what is needed is a method and system for forming a contact in a thin-film device that is less complex and minimizes any potential shorting of the resulting device. The device and method should be simple, inexpensive and capable of being easily adapted to existing technology. The present invention addresses this need.

### SUMMARY OF THE INVENTION

An aspect of the present invention is a method of forming a contact in a thin-film device. The method includes forming a liftoff stencil, depositing at least one material through the liftoff stencil, removing a portion of the liftoff stencil, depositing a dielectric material, planarizing the dielectric material thereby exposing a portion of the at least one material and depositing a conductor material in contact with the exposed portion of the at least one material.

Other aspects and advantages of the present invention will become apparent from the following detailed description, taken in conjunction with the accompanying drawings, illustrating by way of example the principles of the invention.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated, and implications to the contrary are otherwise not to be made.

FIG. 1 is a high-level flow chart of a method in accordance with an embodiment of the present invention.

FIG. 2A shows a structure whereby three different layers of material are employed to create a liftoff stencil in accordance with an embodiment of the present invention.

FIG. 2B shows the structure after the deposition of a bottom conductor and TMR junction material in accordance with an embodiment of the present invention.

FIG. 2C shows the structure after the deposition of the hardmask layer in accordance with an embodiment of the present invention.

FIG. 2D shows the structure after the first and second photo-resists have been selectively removed in accordance with an embodiment of the present invention.

FIG. 2E shows the structure after the deposition of the dielectric material in accordance with an embodiment of the present invention.

FIG. 2F shows the structure after the completion of the CMP process whereby a portion of the hardmask layer is exposed in accordance with an embodiment of the present invention.

FIG. 2G shows the structure after the deposition of the top conductor in accordance with an embodiment of the present invention.

FIG. 3 shows a block diagram of a CMP machine.

FIG. 4 is a side partial perspective view of a semiconductor wafer.

### DETAILED DESCRIPTION

The present invention relates to a method and system for forming a contact in a thin-film device. The following description is presented to enable one of ordinary skill in the art to make and use the invention and is provided in the context of a patent application and its requirements. Various modifications to the embodiments and the generic principles and features described herein will be readily apparent to those skilled in the art. Thus, the present invention is not intended to be limited to the embodiment shown but is to be accorded the widest scope consistent with the principles and features described herein.

As shown in the drawings for purposes of illustration, a method and system for forming a contact in a thin-film device is disclosed. Accordingly, a liftoff stencil is implemented with a dielectric material to form a contact in a thin-film device. Consequently, the dielectric material can be utilized as a CMP etch stop during device formation.

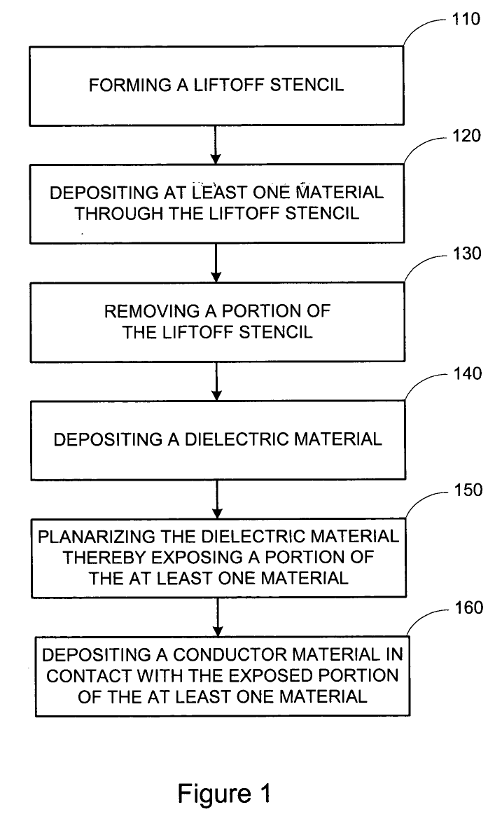

FIG. 1 is a high level flow chart of a method in accordance with an embodiment of the present invention. A first step 110 includes forming a liftoff stencil. A second step 120 includes depositing at least one material through the liftoff stencil. A next step 130 includes removing a portion of the liftoff stencil. A fourth step 140 involves depositing a dielectric material. A fifth step 150 includes etching the dielectric material thereby exposing a portion of the at least one material. A final step 160 involves depositing a conductor material in contact with the exposed portion of the at least one material.

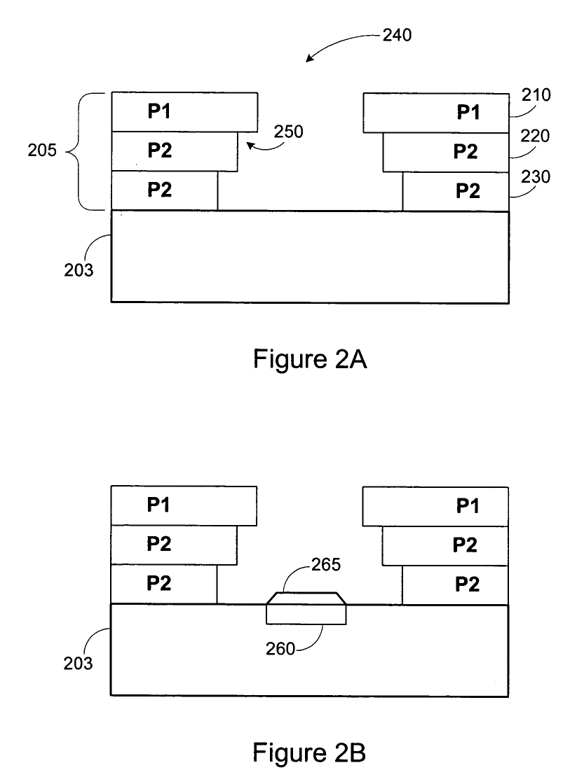

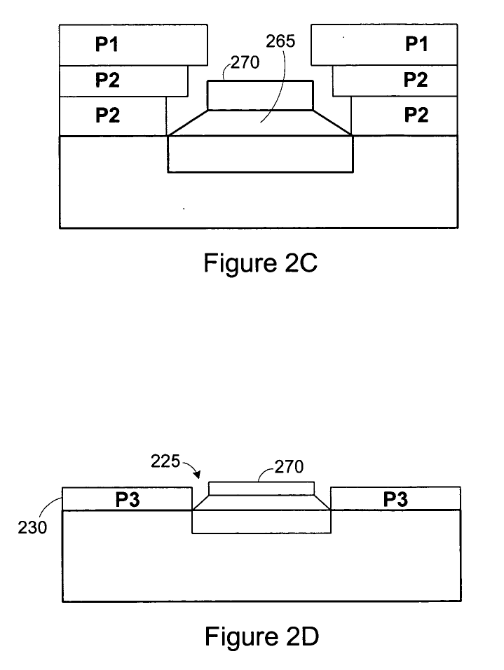

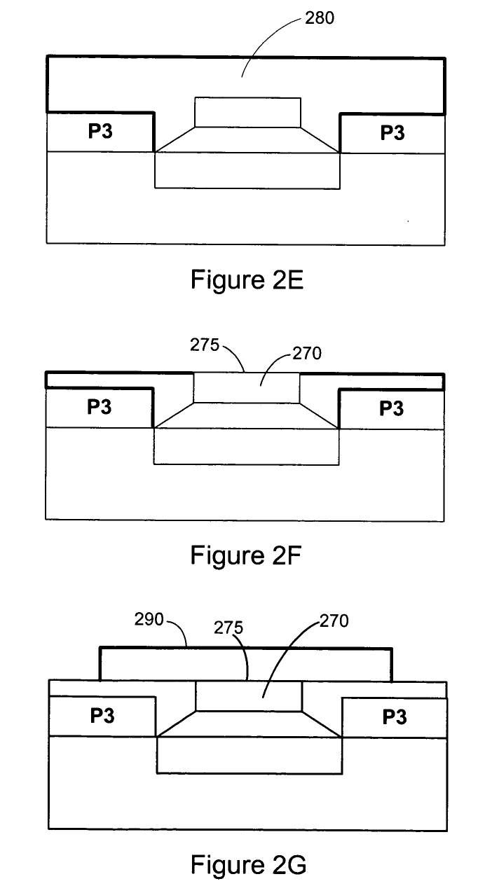

In an embodiment, step 110 is accomplished with three different layers of material. FIG. 2A shows a structure whereby three different layers of material are employed to create a liftoff stencil. As can be seen in FIG. 2A, the liftoff stencil 205 is on a substrate 203 and includes a first layer 210, a second layer 220 and a third layer 230. The distance that the first layer 210 extends past the second layer 220 is defined as an undercut 250. Similarly, the geometries of the first layer 210 determine the size of opening 240 and the second layer 220 facilitates the lift-off process. Although the second layer 220 is included in the described embodiment, the second layer can be omitted and the third layer 230 can serve as an interlayer dielectric.

The first, second and third layers 210, 220, 230 of material can be a variety of different materials. For example, in an embodiment; the first, second and third layers 210, 220, 230 of material are photo-resist materials whereby each layer of photo-resist material is capable of being etched in a selective fashion. It should be understood that one of ordinary skill in the art will readily recognize that a variety of photo-resist materials can be implemented.

Additionally, although the liftoff stencil 205 is described as being formed photo-resist material, one of ordinary skill will readily recognize that the liftoff stencil 205 can be formed with a variety of different materials. For example, at least one the layers 210, 220, 230 can be a dielectric material such as a spin-on glass (SOG) material, SiO₂, Si₃N₄, Al₂O₃ or any of a variety of dielectric materials.

In an embodiment, step 120 is accomplished by utilizing deposition techniques to deposit at least one material through the opening 240. In an MRAM device for example, this step involves the deposition of requisite materials for forming a magnetic memory element. A magnetic memory element of is an element having a resistance that is dependent upon the magnetic state thereof. Examples of such elements include magnetic tunnel junctions (MJTs) and giant magnetoresistance (“GMR”) spin valves. Such elements include two ferromagnetic films (e.g. NiFe or CoFe) with a non-magnetic spacer between them. In the case of an MTJ memory element, the spacer is an insulator (for example Al₂O₃) whereas for a GMR memory element the spacer is a conductor (for example, Cu).

Although the embodiment is described in conjunction with the formation of an MRAM device, one of ordinary skill in the art will readily recognize that the described processes could be implemented in conjunction with the formation of a variety of different types of devices while remaining within the spirit and scope of the present invention.

Step 120 is accordingly accomplished by first depositing a magnetic memory element material stack 265 through the opening 240 onto a previously patterned bottom conductor 260 wherein the bottom conductor 260 is a conductive material such as Cu, Au, Ag, Pt, Al, Ta or any combination thereof. Opening 240 defines the size and shape of the magnetic memory element 265. In an embodiment, the magnetic memory element 265 is an MTJ and is made up of an insulator layer sandwiched between two ferromagnetic layers. FIG. 2B shows the structure including the bottom conductor 260 and the magnetic memory element 265.

After depositing a magnetic memory element 265, an optional hardmask layer 270 is deposited in contact with the TMR junction 265. In varying embodiments, the hardmask layer 270 is a metal layer or other layers such as silicon oxide, silicon nitride, silicon carbide, tantalum nitride and tungsten nitride. FIG. 2C shows the structure after the deposition of the hardmask layer 270.

In an embodiment, the hardmask layer 270 is deposited by a collimated deposition method, such as thermal or electron beam evaporation, to create a sharp edge profile in the hardmask layer 270 as depicted in FIG. 2C. Accordingly, hardmask layer 270 can be utilized to protect the magnetic memory element 265 in a subsequent etch step that can be introduced to better define the perimeter of the magnetic memory element 265.

Referring back to FIG. 1, step 130 is accomplished by selectively removing the first layer of photo-resist 210 and the second layer of photo-resist 220 thereby leaving the third layer of photo-resist 230. This is accomplished by selectively etching the first and second photo-resists 210, 220. FIG. 2D shows the structure after the first and second layers of photo-resists 210, 220 have been selectively removed. As can be seen in FIG. 2D, there is a gap 225 between the third layer of photo-resist 230 and the hardmask layer 270. Additionally, the third layer of photo-resist 230 has a thickness less than the combined thickness of the magnetic memory element 265 and the hardmask layer 270.

Following the removal of the first and second photo-resist layers 210, 220 the structure can be etched to remove magnetic memory material in the gap 225, using the hardmask layer 270 to protect the interior of the magnetic memory element 265. This step is optional and is implemented to create a well-defined perimeter on the magnetic memory element 265 and to remove any potential shorting paths.

Step 140 involves depositing a dielectric material into the gap 225. In an embodiment, material 280 is a dielectric such as a spin-on glass (SOG), SiO₂, Si₃N₄, Al₂O₃ or any of a variety of dielectric materials. Dielectric material is advantageous in this instance because the filling properties of dielectric materials allow the gaps 225 to be more easily filled and the electrically insulating nature of the material prevents shorting in the resulting device. FIG. 2E shows the structure after the deposition of the dielectric material 280. Additionally, the deposition of a dielectric material 280 in this instance, allows a planarization process to be subsequently implemented.

Accordingly step 150 serves as a planarization step and is accomplished by utilizing a chemical mechanical polishing (CMP) process. CMP removes material from the top layer of a substrate in the production of ultra-high density integrated circuits. In a typical CMP process, the top layer is exposed to an abrasive medium under controlled chemical, pressure, velocity, and temperature conditions. Conventional abrasive media comprises slurry solutions and polishing pads. The slurry solution can be provided shortly before use by mixing a so-called precursor with an oxidizing agent. The precursor lacks the oxidizing agent, but includes the other components of the slurry (e.g., abrasive media, catalysts, water).

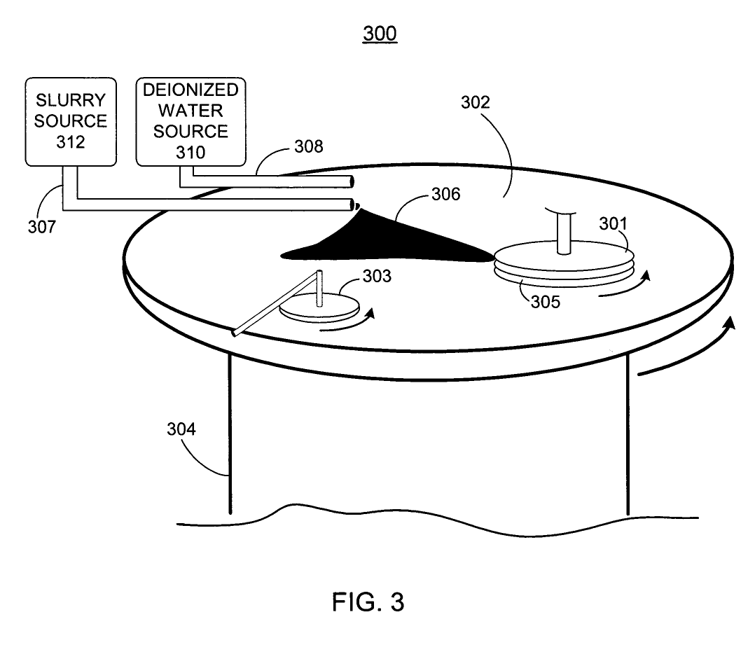

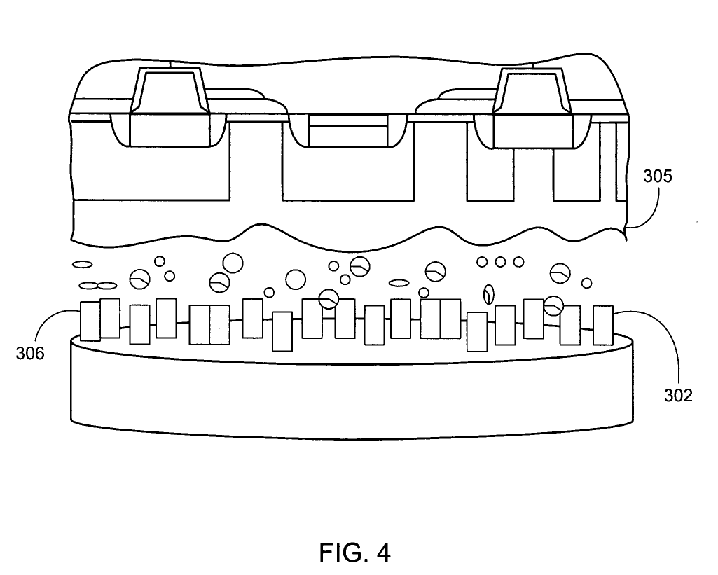

Referring now to FIGS. 3 and 4, there is shown a block diagram of a CMP machine 300 including a rotary process table and a side partial perspective view of a semiconductor wafer 305 (FIG. 4). The CMP machine 300 is fed wafers to be polished by an arm 301 and places them onto a rotating polishing pad 302. The polishing pad 302 is made of a resilient material and is textured, often with a plurality of predetermined grooves, to aid the polishing process. A conditioning arm 303 conditions the polishing pad. A wafer is held in place on the polishing pad 302 by the arm 301 with a predetermined amount of down force.

During polishing, the lower surface of the wafer 305 rests against the polishing pad 302. As the polishing pad 302 rotates, the arm 301 rotates the wafer 305 at a predetermined rate. The CMP machine 300 also includes a slurry dispense tube 307, extending across the radius of the polishing pad 302. The slurry dispense tube 307 dispenses a flow of slurry 306 onto the polishing pad 302 from the slurry source 312. Typically, the polishing pad 302 is primed with slurry 306 for about 8 seconds. The slurry 306 is a mixture of de-ionized water and polishing agents designed to aid chemically the smooth and predictable planarization of the wafer. The rotating action of both the polishing pad 302 and the wafer 305, in conjunction with the polishing action of the slurry, combine to planarize, or polish, the wafer 305 at some nominal rate. In current systems using silica slurry the pH of the slurry is very high, typically having a pH of around 10 or 11.

After the slurry dispense process is terminated, de-ionized water is dispensed from the de-ionized water source 310 via the water dispense tube 308 onto the pad. The wafer substrate is then rid of the slurry. FIG. 2F shows the structure after the completion of the CMP process whereby a portion 275 of the hardmask layer 270 is exposed.

Although the above-described embodiment discloses the employment of a CMP etch process, one of ordinary skill in the art will readily recognize that a variety of other etch processes are capable of being implemented while remaining within the spirit and scope of the present invention.

Finally, step 160 is accomplished by depositing a top conductor 280 in contact with the exposed portion 275 of the hardmask layer 270 wherein the top conductor 280 is a conductive material such as Cu, Au, Ag, Pt, Al, Ta or any combination thereof. FIG. 2G shows the structure after the deposition of the top conductor 280.

In the above-described embodiment, the hardmask layer 270 is utilized as an etch stop for the CMP process. If the hardmask layer 270 is to remain in the finished device, the hardmask layer 270 is an electrically conducting material such as tantalum nitride or tungsten nitride. Alternatively, the hardmask layer 270 can be removed prior to depositing the top conductor 280. Furthermore, if the third layer 230 of the liftoff stencil is a dielectric material, the hardmask layer 270 can be removed and the third layer 230 can be utilized as an etch stop for the CMP process.

Various embodiments of a method and system for forming a contact in a memory device are disclosed. Accordingly, a liftoff stencil is implemented with a dielectric material to form a contact in a thin-film device. Consequently, the dielectric material can be utilized as a CMP etch stop during device formation.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. A method of forming a contact in a thin-film device comprising:
forming a liftoff stencil;
depositing at least one material through the liftoff stencil;
removing a portion of the liftoff stencil;
depositing a dielectric material;
planarizing the dielectric material thereby exposing a portion of the at least one material; and
depositing a conductor material in contact with the exposed portion of the at least one material.

2. The method of claim 1 wherein forming the liftoff stencil further comprises:
utilizing at least one layer of photo-resist to form the liftoff stencil wherein the liftoff stencil includes an undercut.

3. The method of claim 1 wherein depositing a dielectric material further comprises:
depositing a spin on glass material.

4. The method of claim 1 wherein planarizing the dielectric material further comprises:
utilizing a chemical-mechanical polishing process to etch the dielectric layer.

5. The method of claim 1 wherein the thin-film device is a magnetic random access memory device.

6. The method of claim 1 wherein the at least one material comprises a hardmask layer.

7. The method of claim 1 wherein removing a portion of the liftoff stencil further comprises removing the first and second layers of photo-resist.

8. The method of claim 2 wherein the at least one layer of photo-resist further comprises a first layer of photo-resist and a second layer of photo-resist.

9. The method of claim 2 wherein forming the liftoff stencil further comprises utilizing at least one layer of dielectric material.

10. The method-of claim 4 wherein the dielectric layer comprises a spin-on-glass material.

11. The method of claim 5 wherein depositing at least one material through the liftoff stencil further comprises:
depositing magnetic memory material.

12. The method of claim 6 wherein the hardmask layer comprises at least one of silicon oxide, silicon nitride, silicon carbide, tantalum nitride and tungsten nitride.

13. The method of claim 6 further comprising etching the at least one material using the hardmask layer as etch mask.

14. The method of claim 6 wherein the hardmask layer is comprised of an electrically conducting material.

15. The method of claim 6 wherein depositing the hardmask layer comprises depositing the hardmask layer in a directional fashion.

16. The method of claim 6 wherein the liftoff stencil includes at least one dielectric layer and planarizing further comprises:
removing the hardmask layer;
utilizing the at least one dielectric layer as an etch stop.

17. The method of claim 7 wherein the at least one layer of photo-resist includes a third layer of photo-resist wherein the third layer of photo-resist has a thickness less than a thickness of the at least one material.

18. The method of claim 8 wherein the at least one layer of dielectric material comprises at least one of SOG, silicon oxide, silicon nitride, silicon carbide, aluminum oxide and aluminum nitride.

19. A system of forming a contact in a semiconductor device comprising:
means for creating a liftoff stencil;
deposition means for depositing at least one material through the liftoff stencil wherein the at least one material includes a hardmask layer;
means for selectively removing a portion of the liftoff stencil;
means for depositing a dielectric material;
means for removing a portion of the dielectric material thereby exposing a portion of the at least one material; and
means for providing a conductor material in contact with the exposed portion of the at least one material.

20. The system of claim 19 wherein the means for creating a liftoff stencil further comprises:
means for utilizing at least one layer of photo-resist to form the liftoff stencil wherein the liftoff stencil includes an undercut.

21. The system of claim 19 wherein the means for depositing a dielectric material further comprises:
means for depositing a spin on glass material.

22. The system of claim 19 wherein the means for planerizing the dielectric material further comprises a chemical-mechanical polisher.

23. The system of claim 19 wherein the thin-film device is a magnetic random access memory device.

24. The system of claim 19 wherein the hardmask layer comprises at least one of silicon oxide, silicon nitride, silicon carbide, tantalum nitride and tungsten nitride.

25. The system of claim 19 wherein means for removing a portion of the dielectric material comprises means for etching the dielectric material using the hardmask layer as an etch stop.

26. The system of claim 16 wherein means for selectively removing a portion of the liftoff stencil further comprises:
removing the first and second layers of photo-resist.

27. The system of claim 20 wherein the at least one layer of photo-resist includes a third layer of photo-resist wherein the third layer of photo-resist has a thickness less than a thickness of the at least one material.

28. The system of claim 24 wherein the means for depositing the at least one material comprises means for depositing the hardmask layer in a directional fashion.

29. The system of claim 11 wherein the at least one layer of dielectric material comprises at least one of SOG, silicon oxide, silicon nitride, silicon carbide, aluminum oxide and aluminum nitride.

30. A method of forming a contact in a magnetic random access memory device comprising:
forming a liftoff stencil with at least one layer of dielectric material;
depositing magnetic memory material in contact with a previously deposited bottom conductor;
depositing a hardmask layer in contact with the magnetic memory material;
removing a portion of the liftoff stencil;
depositing a dielectric material;
planarizing the dielectric material thereby exposing a portion of the hardmask layer; and
depositing a conductor material in contact with the exposed portion of the hardmask layer.

31. The method of claim 30 wherein the at least one layer of dielectric material has a thickness less than a combined thickness of the magnetic memory material and the hardmask layer.

32. The method of claim 30 wherein depositing a dielectric material further comprises:
depositing a spin on glass material.

33. The method of claim 30 wherein the hardmask layer is comprised of an electrically conducting material.

34. The method of claim 32 wherein planarizing the dielectric material further comprises:
utilizing a chemical-mechanical polishing process to etch the spin on glass material.
